(19) United States
(12) Patent Application Publication
(10) Pub. No.: US 2016/0319432 A1
(43) Pub. Date: Nov. 3, 2016

(54) LAMINATE FILM, ORGANIC ELECTROLUMINESCENT DEVICE, PHOTOELECTRIC CONVERSION DEVICE, AND LIQUID CRYSTAL DISPLAY

(71) Applicant: SUMITOMO CHEMICAL COMPANY, LIMITED, Tokyo (JP)

(72) Inventor: Akira HASEGAWA, Tsukuba-shi (JP)

(73) Assignee: SUMITOMO CHEMICAL COMPANY, LIMITED, Tokyo (JP)

(21) Appl. No.: 15/107,525

(22) PCT Filed: Dec. 11, 2014
(86) PCT No.: PCT/JP2014/083494

§ 371 Date: Jun. 23, 2016

(30) Foreign Application Priority Data
Dec. 26, 2013 (JP) 2013-268639

(51) Int. Cl. C23C 16/50; C23C 16/42

(52) U.S. Cl. CPC C23C 16/50; C23C 16/42

(57) ABSTRACT

Provided is laminate film having a substrate and at least one thin film layer which has been formed on at least one surface of the substrate, wherein at least one thin film layer satisfies all of conditions (i) to (iii) below:
(i) the thin film layer contains silicon atoms, oxygen atoms, carbon atoms, and hydrogen atoms,
(ii) in a silicon distribution curve, an oxygen distribution curve, and a carbon distribution curve respectively showing a relationship between a distance from a surface of the thin film layer in a thickness direction of the thin film layer and a ratio of an amount of silicon atoms (atomic ratio of silicon), a ratio of an amount of oxygen atoms (atomic ratio of oxygen), and a ratio of an amount of carbon atoms (atomic ratio of carbon), relative to a sum amount of the silicon atoms, the oxygen atoms and the carbon atoms which are contained in the thin film layer at a position located at the aforesaid distance, each the silicon distribution curve, the oxygen distribution curve, and the carbon distribution curve are continuous, and the carbon distribution curve has at least one extremal value, and
(iii) When the thin film layer is supposed as a laminate made of plurality of layers that is modeled under conditions below, a density X (g/cm³) of a layer A that is closest to a substrate side and a density Y (g/cm³) of a layer B having a highest density other than the layer A satisfy a condition represented by formula (1) below:

X<Y (1),

where the modelizing conditions are such that:
one thin film layer is supposed to be a laminate model made of a plurality of layers; a density within each layer and a compositional ratio of atoms constituting each layer are assumed to be constant; a thickness, a density, and a compositional ratio of elements in each layer are respectively set to meet conditions below; the laminate model is set so that a thickness of each layer is 10% or more of a thickness of a whole layer, and integrated values of spectra of the laminate film that are obtained by Rutherford backscattering (160°) and hydrogen forward scattering (30°) and calculated values of spectra that are calculated from the laminate model respectively fall within an error of 5%.

### TECHNICAL FIELD

The present invention relates to a laminate film, an organic electroluminescence device, a photoelectric conversion device, and a liquid crystal display.

### BACKGROUND ART

A gas-barrier film can be suitably used as a packaging container for filling and packaging articles such as drinks and foods, cosmetics, and detergents. In recent years, there has been a proposal for a laminate film having a gas barrier property which is obtained by using a plastic film or the like as a substrate and laminating a thin film of silicon oxide, silicon nitride, silicon oxynitride, aluminum oxide, or the like on one surface of the substrate. For example, Patent Document 1 discloses a laminate film obtained by using an organic silicon compound gas and an oxygen gas as raw materials and forming a thin film layer on a plastic film by the CVD method.

### PRIOR ART DOCUMENT

### Patent Document

Patent Document 1: JP-A-2008-179102

### SUMMARY OF THE INVENTION

### Problems to be Solved by the Invention

However, the aforementioned laminate film has not been sufficiently satisfactory in terms of the gas barrier property.

The present invention has been made in view of such circumstances, and an object thereof is to provide a laminate film having a high gas barrier property. Also, another object of the present invention is to provide an organic electroluminescence device, a photoelectric conversion device, and a liquid crystal display each having the laminate film.

### Means for Solving the Problems

In order to solve the aforementioned problems, one aspect of the present invention provides a laminate film having a substrate and at least one thin film layer which has been formed on at least one surface of the substrate, wherein at least one thin film layers satisfies all of conditions (i) to (iii) below:

(i) the thin film layer contains silicon atoms, oxygen atoms, carbon atoms, and hydrogen atoms,
(ii) in a silicon distribution curve, an oxygen distribution curve, and a carbon distribution curve respectively showing a relationship between a distance from a surface of the thin film layer in a thickness direction of the thin film layer and a ratio of an amount of silicon atoms (atomic ratio of silicon), a ratio of an amount of oxygen atoms (atomic ratio of oxygen), and a ratio of an amount of carbon atoms (atomic ratio of carbon), relative to a sum amount of the silicon atoms, the oxygen atoms and the carbon atoms which are contained in the thin film layer at a position located at the aforesaid distance, each the silicon distribution curve, the oxygen distribution curve, and the carbon distribution curve are continuous, and the carbon distribution curve has at least one extremal value, and
(iii) when the thin film layer is supposed as a laminate made of plurality of layers that is modeled under conditions below, a density X (g/cm³) of a layer A that is closest to a substrate side and a density Y (g/cm³) of a layer B having a highest density other than the layer A satisfy a condition represented by formula (1) below:

X<Y (1),

where modelizing conditions are such that:

one thin film layer is supposed to be a laminate model made of a plurality of layers; a density within each layer and a compositional ratio of atoms constituting each layer are assumed to be constant; a thickness, a density, and a compositional ratio of elements in each layer are respectively set to meet conditions below; the laminate model is set so that a thickness of each layer is 10% or more of a thickness of a whole layer, and integrated values of spectra of the laminate film that are obtained by Rutherford backscattering (160°) and hydrogen forward scattering (30°) and calculated values of the spectra that are calculated from the laminate model respectively fall within an error of 5%.

In one aspect of the present invention, the density Y is preferably 1.34 g/cm³ to 2.65 g/cm³.

In one aspect of the present invention, the density Y is preferably 1.80 g/cm³ to 2.65 g/cm³.

In one aspect of the present invention, the density X is preferably 1.33 g/cm³ to 2.62 g/cm³.

One aspect of the present invention provides an organic electroluminescence device having the laminate film described above.

One aspect of the present invention provides a photoelectric conversion device having the laminate film described above.

One aspect of the present invention provides a liquid crystal display having the laminate film described above.

### Effect of the Invention

According to the present invention, a laminate film having a high gas barrier property can be provided. Also, an organic electroluminescence device, a photoelectric conversion device, and a liquid crystal display each having the laminate film can be provided.

### BRIEF DESCRIPTION OF THE DRAWINGS

FIG. 1 is a schematic view showing an example of a laminate film of the present embodiment.

FIG. 2 is a schematic view showing one example of a production apparatus used for producing a laminate film.

FIG. 3 is a lateral sectional view of an organic electroluminescence device of the present embodiment.

FIG. 4 is a lateral sectional view of a photoelectric conversion device of the present embodiment.

FIG. 5 is a lateral sectional view of a liquid crystal display of the present embodiment.

FIG. 6 is a graph showing a silicon distribution curve, an oxygen distribution curve, and a carbon distribution curve of a thin film layer of a laminate film 1 obtained in Example 1.

FIG. 7 is a graph showing a silicon distribution curve, an oxygen distribution curve, and a carbon distribution curve of a thin film layer of a laminate film 2 obtained in Comparative Example 1.

### MODE FOR CARRYING OUT THE INVENTION

### [Laminate Film]

The laminate film of the present embodiment is a laminate film described above.

Hereafter, the laminate film according to the present embodiment will be described with reference to the drawings. Here, in all of the following drawings, dimension, ratio, and the like of each of the constituent elements have been modified as appropriate in order to make it easier to see the drawings.

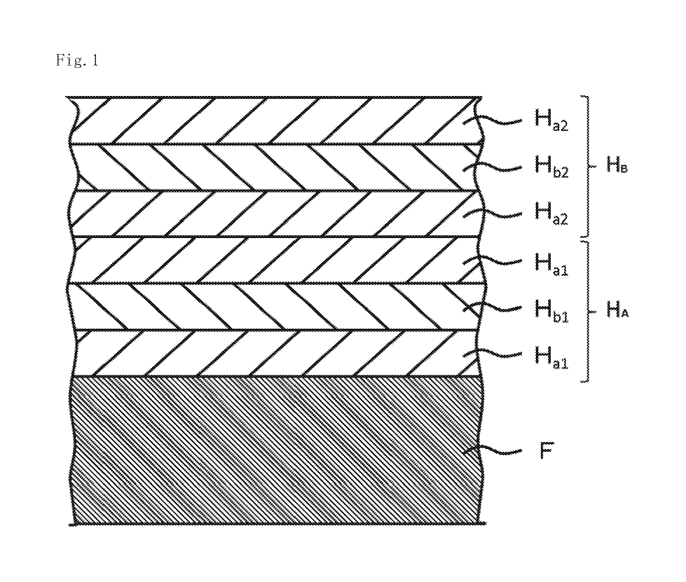

FIG. 1 is a schematic view showing an example of the laminate film of the present embodiment. In the laminate film of the present embodiment, the thin film layer H having a gas barrier property is laminated on the surface of a substrate F. In the laminate film, a plurality of the same or different thin film layers H may be present, and a later-described layer other than the thin film layer H may be present. The thin film layer H contains silicon atoms, oxygen atoms, carbon atoms, and hydrogen atoms. The thin film layer H has a layer: H_{A} and a layer: H_{B} which are described later. Further, the layer: H_{A} includes a first layer Ha₁ which contains a large amount of SiO₂ generated by complete oxidation reaction of a film-forming gas which will be described later, and a second layer Hb₁ which contains a large amount of SiOₓC_{y} generated by incomplete oxidation reaction. The layer: H_{A} has a three-layer structure in which the first layer Ha₁ and the second layer Hb₁ are alternately laminated on each other. Similarly, the layer: H_{B} includes a first layer Ha₂ which contains a large amount of SiO₂ generated by complete oxidation reaction, and a second layer Hb₂ which contains a large amount of SiOₓC_{y} generated by incomplete oxidation reaction. The layer: H_{B} has a three-layer structure in which the first layer Ha₂ and the second layer Hb₂ are alternately laminated on each other.

However, FIG. 1 schematically shows that there is a distribution of film composition, so that in reality there is no clear interface between the layer: H_{A} and the layer: H_{B}, and the composition changes continuously. Also, there is no clear interface between the first layer Ha₁ and the second layer Hb₁ or between the first layer Ha₂ and the second layer Hb₂, and the composition changes continuously. Conversely, between the thin film layer H and another thin film layer H, the composition is discontinuous.

A method for producing the laminate film shown in FIG. 1 will be described later in detail.

### (Substrate)

The substrate F included in the laminate film of the present embodiment is usually a flexible film formed of a polymer material.

When the laminate film of the present embodiment has light permeability, examples of the material for forming the substrate F include polyester resins such as polyethylene terephthalate (PET) and polyethylene naphthalate (PEN); polyolefin resins such as polyethylene (PE), polypropylene (PP), and cyclic polyolefin; polyamide resins; polycarbonate resins; polystyrene resins; polyvinyl alcohol resins; saponified substances of ethylene-vinyl acetate copolymers; polyacrylonitrile resins; acetal resins; and polyimide resins. Among these resins, polyester-based resins or polyolefin-based resins are preferable, and PET or PEN as the polyester-based resins is more preferable in terms of high heat resistance and small linear expansion coefficient. The above resins may be used either individually as one kind or in combination of two or more kinds.

The surface of these resins may be coated with other resins for the purpose of flattening or the like, for use as the substrate F.

Furthermore, when the light permeability of the laminate film is not considered as being important, composite materials obtained by adding a filler, an additive or the like to the above resins, for example, can be used as the substrate F.

The thickness of the substrate F may be appropriately set in consideration of the safety at the time of producing the laminate film. However, the thickness is preferably 5 μm to 500 μm, since the substrate may be easily transported even in vacuum. When the thin film layer H adopted in the present embodiment is formed by the plasma chemical vapor deposition method (plasma CVD method), electric discharge is generated through the substrate F, and consequently, the thickness of the substrate F is more preferably 50 μm to 200 μm, and particularly preferably 50 μm to 100 μm.

In addition, in order to enhance the adhesiveness between the substrate F and the thin film layer to be formed, the substrate F may be subjected to a surface activating treatment for cleaning the surface. Examples of the surface activating treatment include corona treatment, plasma treatment, and flame treatment.

### (Thin Film Layer)

The thin film layer H included in the laminate film of the present embodiment is a layer that is formed on at least one surface of the substrate F, and at least one layer contains silicon atoms, oxygen atoms, carbon atoms, and oxygen atoms. The thin film layer H may further contain nitrogen atoms and aluminum atoms. The thin film layer H may be formed on both surfaces of the substrate F.

In the thin film layer H included in the laminate film of the present embodiment, when the thin film layer is supposed as a laminate made of plurality of layers that is modeled under conditions below, a density X (g/cm³) of a layer A that is closest to the substrate side and a density Y (g/cm³) of a layer B having the highest density other than the layer A satisfy the condition represented by the following formula (1):

X<Y (1).

Preferably, 1.01≦Y/X≦2.00 is satisfied. The value of Y/X is more preferably 1.02 or more, still more preferably 1.04 or more. Also, the value of Y/X is more preferably 1.80 or less, still more preferably 1.50 or less.

Next, the modelizing conditions will be described. The thin film layer H is supposed to be a laminate model made of a plurality of layers. The density within each layer and the compositional ratio of atoms constituting each layer are assumed to be constant. Next, the thickness, the density, and the compositional ratio of elements in each layer are respectively set to meet the following conditions. The laminate model is set so that the thickness of each layer is 10% or more of the thickness of the whole layer, and the integrated values of spectra of the laminate film that are obtained by Rutherford backscattering (160°) and hydrogen forward scattering (30°) and the calculated values of spectra that are calculated from the laminate model respectively fall within an error of 5%. Further, it is preferable that the laminate model is set so that the integrated values of the spectra of the laminate film that are obtained by Rutherford backscattering (115°) and the calculated values of the spectra that are calculated from the laminate model respectively fall within an error of 5%. The angle shown herein can be changed by several degrees. A method to be used for calculating the spectra from the laminate model may be a general simulation method. When elements other than silicon atoms, oxygen atoms, carbon atoms, and hydrogen atoms are present, the element species are determined in advance by XPS or the like, and a model including those elements is prepared. An element contained at 1 at % or more in the thin film layer H is preferably incorporated into the model.

When the thin film layer H included in the laminate film of the present embodiment can be approximated by two layers, one of the two layers that is in contact with the interface of the substrate is the layer A, and the other layer is the layer B. When the thin film layer H can be approximated by three layers, the layer that is in contact with the interface on the substrate side among the three regions is the layer A, and one of the remaining two layers that has a higher average density is the layer B. Similarly, when the thin film layer H has four or more layers, the layer that is in contact with the interface on the substrate side is the layer A, and one of the remaining three or more layers that has the highest average density is set to be the layer B.

The density Y of the layer B is preferably 1.34 g/cm³ to 2.65 g/cm³, more preferably 1.80 g/cm³ to 2.65 g/cm³.

The density X of the layer A is preferably 1.33 g/cm³ to 2.62 g/cm³, more preferably 1.80 g/cm³ to 2.00 g/cm³. Needless to say, the values of X and Y fall within values in the above-described ranges within a range of Y>X.

In the present invention, when a layer B having a high density is present, the gas barrier property is improved. The reason therefor is inferred by the present inventors as follows. First, the density of quartz glass (amorphous SiO₂) is 2.22 g/cm³. When the oxygen atoms of the quartz glass in which the content ratio of the number of carbon atoms corresponds to 0 at % are replaced with carbon atoms, there can be considered the case in which the oxygen atom (O: atomic weight of 16) being (minus) divalent and having two covalent bonds is replaced with a methylene group (CH₂: atomic weight of 14) of an atomic group containing a carbon atom, being divalent, and having two covalent bonds, and the case in which the oxygen atom is replaced with a methyl group (CH₃: atomic weight of 15) of an atomic group containing a carbon atom, being monovalent, and having one covalent bond and a hydrogen atom (H: 1). In the case in which the oxygen atom is replaced with a methylene group, when the replacement takes place without destroying the bonding arrangement of the amorphous atoms, the density decreases by an amount of the change in the atomic weight from 16 to 14. Also, a volume increase brought about by extension of the bonding distance causes a decrease in the density. In this case, a high barrier property can be expected because the hydrophobic methylene group is introduced into the amorphous lattice and because the methylene group having a larger occupation volume than the oxygen atom is introduced. On the other hand, in the case in which the oxygen atom is replaced with a methyl group and a hydrogen atom, there is no change in the sum of the atomic weights; however, the bond by the oxygen atom is cleaved, so that it is impossible to make the replacement while maintaining the bonding distance of the original amorphous atoms, whereby a large decrease in the density occurs, and the gas barrier property also decreases.

### (Distribution of Silicon, Carbon, and Oxygen in Thin Film Layer)

Also, the thin film layer H included in the laminate film of the present embodiment satisfies a condition that a silicon distribution curve, an oxygen distribution curve, and a carbon distribution curve respectively showing a relationship between a distance from a surface of the thin film layer H in a thickness direction of the thin film layer H and a ratio of the number of silicon atoms (ratio of the number of silicon atoms), a ratio of the number of oxygen atoms (ratio of the number of oxygen atoms), and a ratio of the number of carbon atoms (ratio of the number of carbon atoms), relative to the sum number of the silicon atoms, the oxygen atoms and the carbon atoms at a position located at the aforesaid distance, are each continuous.

Also, the carbon distribution curve has at least one extremal value.

Hereafter, the distribution curve of each element will be described first, and subsequently, the condition that each the silicon distribution curve, the oxygen distribution curve, and the carbon distribution curve are continuous, and successively, the condition that the carbon distribution curve has at least one extremal value, will be described.

The silicon distribution curve, the oxygen distribution curve, and the carbon distribution curve can be prepared by performing so-called XPS depth profile measurement in which sequential surface composition analysis is performed in a state where the inside of a sample is being exposed to the outside, by concurrently performing measurement of X-ray photoelectron spectroscopy (XPS: X-ray Photoelectron Spectroscopy) and ion sputtering utilizing a noble gas such as an argon gas.

The distribution curves obtained by XPS depth profile measurement are determined such that the ordinate represents a ratio of the number of atoms of the element (unit: at %), and the abscissa represents an etching time. In performing the XPS depth profile measurement, it is preferable to adopt the noble gas ion sputtering method utilizing argon (Ar⁺) as an etching ion species and to set the etching speed (etching rate) to 0.05 nm/sec (value as converted in terms of SiO₂ thermal oxide film).

However, SiOₓC_{y} contained in a large amount in the second layer is etched more rapidly than the SiO₂ thermal oxide film. Therefore, 0.05 nm/sec which is the etching speed of the SiO₂ thermal oxide film is used as a rough indication of the etching conditions. That is, in a strict sense, a product of 0.05 nm/sec which is the etching speed and the etching time taken for etching the film up to the substrate F does not represent the distance between the surface of the thin film layer H and the substrate F.

Therefore, the thickness of the thin film layer H is determined by separate measurement and, based on the determined thickness and the etching time taken for etching the film up to the substrate F from the surface of the thin film layer H, the “distance from the surface of the thin film layer H in the thickness direction of the thin film layer H” is made to correspond to the etching time.

In this manner, it is possible to prepare each element distribution curve in which the ordinate represents the ratio of the number of atoms of each element (unit: at %), and the abscissa represents the distance (unit: nm) from the surface of the thin film layer H in the thickness direction of the thin film layer H.

First, the thickness of the thin film layer H is determined by observing a cross-section of a slice of the thin film layer, which is prepared by FIB (Focused Ion Beam) process, with TEM.

Thereafter, based on the obtained thickness and the etching time taken for etching the film up to the substrate F from the surface of the thin film layer H, the “distance from the surface of the thin film layer H in the thickness direction of the thin film layer H” is made to correspond to the etching time.

In the XPS depth profile measurement, when an etching region moves from the thin film layer H formed of materials such as SiO₂ and SiOₓC_{y} to the substrate F formed of materials such as a polymer material, the measured ratio of the number of carbon atoms rapidly increases. Therefore, in the present invention, the time when a gradient attains a maximum in the region in which the “ratio of the number of carbon atoms rapidly increases” in the XPS depth profile is taken as an etching time corresponding to the boundary between the thin film layer H and the substrate F in the XPS depth profile measurement.

When the XPS depth profile measurement is performed discretely with respect to the etching time, a time when a difference of the measured values in the ratio of the number of carbon atoms between two adjacent points attains the maximum in the measured time is extracted, and a midpoint between the two points is taken as the etching time corresponding to the boundary between the thin film layer H and the substrate F.

When the XPS depth profile measurement is performed continuously with respect to the thickness direction, in the region in which the “ratio of the number of carbon atoms rapidly increases”, a point at which a time differential value attains a maximum in a graph showing the ratio of the number of carbon atoms relative to the etching time is taken as the etching time corresponding to the boundary between the thin film layer H and the substrate F.

In other words, by making the thickness of the thin film layer, which is obtained by observing the cross-section of a slice of the thin film layer with TEM, correspond to the “etching time corresponding to the boundary between the thin film layer H and the substrate F” in the XPS depth profile, it is possible to prepare each element distribution curve in which the ordinate represents the ratio of the number of atoms of each element, and the abscissa represents the distance from the surface of the thin film layer H in the thickness direction of the thin film layer H.

When the condition that the ratio of the number of silicon atoms, the ratio of the number of oxygen atoms and the ratio of the number of carbon atoms in the thin film layer H are each continuous is satisfied, the obtained laminate film hardly causes occurrence of peeling-off from a discontinuous interface or the like.

The state in which each the silicon distribution curve, the oxygen distribution curve, and the carbon distribution curve are continuous refers to a state in which the silicon distribution curve, the oxygen distribution curve, and the carbon distribution curve do not have a part where the ratio of the number of silicon atoms, the ratio of the number of oxygen atoms and the ratio of the number of carbon atoms discontinuously change. Specifically, this refers to a state in which the relationship between the distance (x, unit: nm) from the surface of the thin film layer H in the thickness direction of the layer and the ratio of the number of silicon atoms (C_{Si}, unit: at %), the ratio of the number of oxygen atoms (C_{O}, unit: at %), and the ratio of the number of carbon atoms (C_{C}, unit: at %) satisfies the conditions represented by the following numerical formulae (F1) to (F3):

|dC_{Si}/dx|≦0.5 (F1)

|dC_{O}/dx|≦0.5 (F2)

|dC_{C}/dx|≦0.5 (F3).

The condition that the thin film layer H has is that, in the thin film layer H, the carbon distribution curve has at least one extremal value.

In the thin film layer H, it is more preferable that the carbon distribution curve has at least two extremal values, particularly preferably at least three extremal values. When the carbon distribution curve does not have an extremal value, the obtained laminate film will have an insufficient gas-barrier property.

When the carbon distribution curve has at least three extremal values, it is preferable that the absolute value of the difference of the distances from the surface of the thin film layer H in the thickness direction of the thin film layer H at one extremal value that the carbon distribution curve has and at an extremal value adjacent to the one extremal value is all 200 nm or less, more preferably 100 nm or less.

In the present specification, an “extremal value” refers to a local maximal value or a local minimal value of the ratio of the number of atoms of an element with respect to the distance from the surface of the thin film layer H in the thickness direction of the thin film layer H in the distribution curve of each element.

In the present specification, the “local maximal value” refers to a point at which the value of the ratio of the number of atoms of an element that has kept increasing begins to decrease when the distance from the surface of the thin film layer H is changed and at which the value of the ratio of the number of atoms of the element, which is at a position determined when the distance from the surface of the thin film layer H in the thickness direction of the thin film layer H is changed further by ±20 nm from the aforementioned point, decreases by 3 at % or more as compared with the value of the ratio of the number of atoms of the element at the aforementioned point.

In the present specification, the “local minimal value” refers to a point at which the value of the ratio of the number of atoms of an element that has kept decreasing begins to increase when the distance from the surface of the thin film layer H is changed and at which the value of the ratio of the number of atoms of the element, which is at a position determined when the distance from the surface of the thin film layer H in the thickness direction of the thin film layer H is changed further by ±20 nm from the aforementioned point, increases by 3 at % or more as compared with the value of the ratio of the number of atoms of the element at the aforementioned point.

In the thin film layer H, it is preferable that the absolute value of a difference between the maximum value and the minimum value of the ratio of the number of carbon atoms in the carbon distribution curve is 5 at % or more.

In the thin film layer H, it is more preferable that the absolute value of the difference between the maximum value and the minimum value of the ratio of the number of carbon atoms is 6 at % or more, particularly preferably 7 at % or more, in a range excluding the depth up to 5%, relative to the thickness of the thin film layer H, in the thickness direction from the surface or the interface between the thin film layer H and another layer described later towards the thin film layer H and the depth up to 5%, relative to the thickness of the thin film layer H, in the thickness direction from the interface between the thin film layer H and the substrate towards the thin film layer H. When the absolute value is 5 at % or more, the gas barrier property of the obtained laminate film is further more enhanced.

In the laminate film of the present embodiment, the thickness of the thin film layer H is preferably within a range of 5 nm or more and 3000 nm or less, more preferably within a range of 10 nm or more and 2000 nm or less, and particularly preferably within a range of 100 nm or more and 1000 nm or less. When the thickness of the thin film layer H is 5 nm or more, the gas barrier properties such as an oxygen gas barrier property and a water vapor barrier property are further improved. When thickness of the thin film layer H is 3000 nm or less, effects in reducing the curl, reducing the coloring, and restraining the deterioration of the gas barrier property caused when the film is bent are produced.

When the laminate film of the present embodiment has a layer obtained by lamination of two or more of the thin film layers H, the value of a sum of the thicknesses of the thin film layers H (thickness of a barrier film obtained by lamination of the thin film layers H) is preferably greater than 100 nm and equal to or less than 3000 nm. When the value of a sum of the thicknesses of the thin film layers H is 100 nm or greater, the gas barrier properties such as an oxygen gas barrier property and a water vapor barrier property are further improved. When the value of a sum of the thicknesses of the thin film layers H is 3000 nm or less, it is possible to obtain a further higher effect of restraining the deterioration of the gas barrier property caused when the film is bent. Furthermore, the thickness of each of the thin film layers H is preferably greater than 50 nm.

### (Other Constitutions)

The laminate film of the present embodiment has the substrate F and the thin film layer H. However, the laminate film may further have other layers such as a primer coating layer, a heat-sealable resin layer, and an adhesive layer in accordance with the needs.

The primer coating layer can be formed of a known primer coating agent which can improve the adhesiveness between the laminate film and another layer. The heat-sealable resin layer can be appropriately formed of a known heat-sealable resin. The adhesive layer can be appropriately formed of a known adhesive. Also, a plurality of laminate films may be bonded to each other with use of the adhesive layer.

The laminate film of the present embodiment has the constitutions described above.

### (Method for Producing Laminate Film)

Next, a method for producing a laminate film according to the present invention will be described.

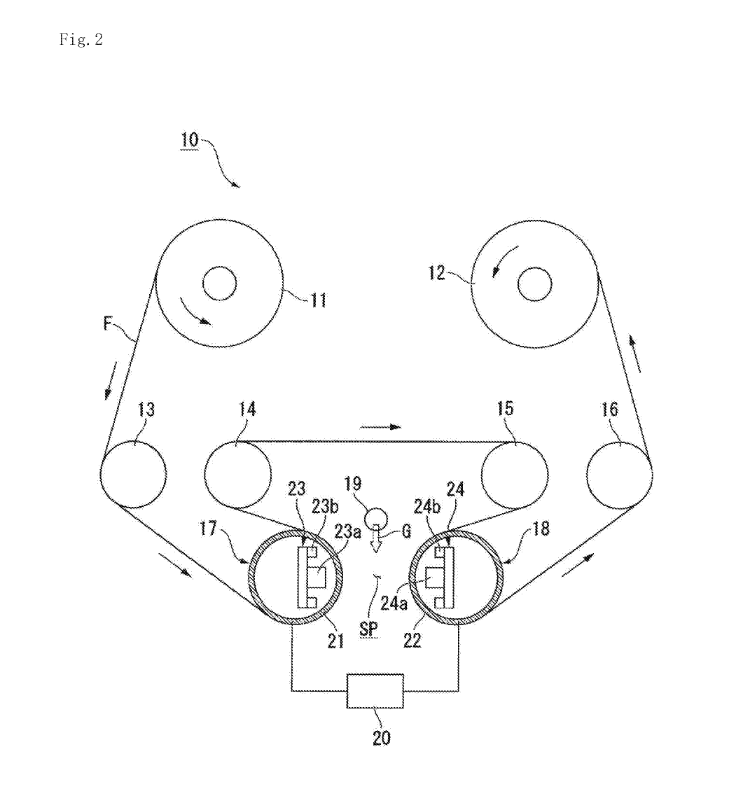

FIG. 2 is a schematic view showing one example of an apparatus for producing a laminate film, and is a schematic view of an apparatus for forming a thin film layer by the plasma chemical vapor deposition method. Here, in FIG. 2, dimension, ratio, and the like of each of the constituent elements have been modified as appropriate in order to make it easier to see the drawings.

A production apparatus 10 shown in FIG. 2 has a feeding roll 11, a winding roll 12, transport rolls 13 to 16, a first film-forming roll 17, a second film-forming roll 18, a gas supplying pipe 19, a power source 20 for plasma generation, an electrode 21, an electrode 22, a magnetic field-forming device 23 disposed inside the first film-forming roll 17, and a magnetic field-forming device 24 disposed inside the second film-forming roll 18.

During the process of producing the laminate film, among the constituent elements of the production apparatus 10, at least the first film-forming roll 17, the second film-forming roll 18, the gas supplying pipe 19, the magnetic field-forming device 23, and the magnetic field-forming device 24 are disposed inside a vacuum chamber not shown in the drawings. The vacuum chamber is connected to a vacuum pump not shown in the drawings. The internal pressure of the vacuum chamber is controlled by operation of the vacuum pump.

If this apparatus is used, by controlling the power source 20 for plasma generation, it is possible to generate an electric discharge plasma of a film-forming gas supplied from the gas supplying pipe 19, in a space between the first film-forming roll 17 and the second film-forming roll 18, whereby it is possible to form a film by plasma CVD through a continuous film-forming process by using the generated electric discharge plasma.

The substrate F which is yet to be subjected to film formation is wound up around the feeding roll 11. The feeding roll 11 feeds the substrate F by winding off the substrate F in a lengthwise direction. The winding roll 12 is disposed in the end side of the substrate F. The winding roll 12 winds up the substrate F which has undergone the film formation while drawing the substrate F, whereby the substrate F is wound up around the roll in the form of a roll.

The first film-forming roll 17 and the second film-forming roll 18 are arranged to extend in parallel with each other to face each other.

Both of the rolls are formed of an electroconductive material and transport the substrate F by rotating respectively. The first film-forming roll 17 and the second film-forming roll 18 preferably have the same diameter, and preferably have a diameter of 5 cm or more and 100 cm or less.

Also, the first film-forming roll 17 and the second film-forming roll 18 are insulated from each other and connected to the common power source 20 for plasma generation. When an alternating-current voltage is applied from the power source 20 for plasma generation, an electric field is formed in a space SP between the first film-forming roll 17 and the second film-forming roll 18. The power source 20 for plasma generation is preferably able to apply an electric power of 100 W to 10 kW, and is preferably able to control the frequency of the alternating current to be 50 Hz to 500 kHz.

The magnetic field-forming device 23 and the magnetic field-forming device 24 are members that form a magnetic field in the space SP, and are contained inside the first film-forming roll 17 and the second film-forming roll 18. The magnetic field-forming device 23 and the magnetic field-forming device 24 are fixed so that the magnetic field-forming device 23 and the magnetic field-forming device 24 may not rotate together with the first film-forming roll 17 and the second film-forming roll 18 (that is, so that the posture thereof relative to the vacuum chamber may not change).

The magnetic field-forming device 23 and the magnetic field-forming device 24 have central magnets 23a and 24a which extend in the same direction as the first film-forming roll 17 and the second film-forming roll 18 extend, and annular external magnets 23b and 24b which surround the central magnets 23a and 24a and are arranged to extend in the same direction as the first film-forming roll 17 and the second film-forming roll 18 extend. In the magnetic field-forming device 23, a magnetic line (magnetic field) connecting the central magnet 23a to the external magnet 23b forms an endless tunnel. Likewise, in the magnetic field-forming device 24, a magnetic line connecting the central magnet 24a to the external magnet 24b forms an endless tunnel.

By magnetron electric discharge caused when the magnetic line intersects with the electric field formed between the first film-forming roll 17 and the second film-forming roll 18, an electric discharge plasma of the film-forming gas is generated. That is, the space SP, which will be described later in detail, is used as a film-forming space for forming a film by plasma CVD. Onto a surface (film-forming surface) of the substrate F that is not in contact with the first film-forming roll 17 and the second film-forming roll 18, the film-forming gas having been in the state of plasma is deposited, whereby the thin film layer is formed.

In the vicinity of the space SP, the gas supplying pipe 19, which supplies the film-forming gas G such as a raw material gas for plasma CVD to the space SP, is disposed. The gas supplying pipe 19 is in the form of a pipe which extends in the same direction as the first film-forming roll 17 and the second film-forming roll 18 extend, and supplies the film-forming gas G to the space SP through openings placed at a plurality of sites of the pipe. In the figure, a state in which the film-forming gas G is supplied to the space SP from the gas supplying pipe 19 is shown by an arrow sign.

The raw material gas may be selected and used appropriately in accordance with the material of the barrier film to be formed. As the raw material gas, for example, organic silicon compounds containing silicon may be used. Examples of the organic silicon compounds include hexamethyldisiloxane, 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, octamethylcyclotetrasiloxane, dimethyldisilazane, trimethyldisilazane, tetramethyldisilazane, pentamethyldisilazane, and hexamethyldisilazane. Among these organic silicon compounds, hexamethyldisiloxane and 1,1,3,3-tetramethyldisiloxane are preferable from the view point of easiness of handling in the compounds and the gas barrier property of the obtained barrier film. These organic silicon compounds may be used either individually as one kind or in combination of two or more kinds. Furthermore, in addition to the aforementioned organic silicon compound, monosilane may be allowed to be contained as the raw material gas, and the thus obtained gas may be used as a silicon source of the barrier film to be formed.

As the film-forming gas, a reactant gas may be used in addition to the raw material gas. As the reactant gas, a gas which reacts with the raw material gas to be turned into an inorganic compound such as an oxide or a nitride may be selected and used. As the reactant gas for forming an oxide, for example, oxygen and ozone may be used. As the reactant gas for forming a nitride, for example, nitrogen and ammonia may be used. These reactant gases may be used either individually as one kind or in combination of two or more kinds. For example, when an oxynitride is to be formed, a reactant gas for forming an oxide and a reactant gas for forming a nitride may be used in combination. The flow rate of the raw material gas is preferably 10 sccm to 1000 sccm (0° C., 1 atm standard). The flow rate of the reactant gas is preferably 100 sccm to 10000 sccm (0° C., 1 atm standard).

The film-forming gas may contain a carrier gas in accordance with needs so as to supply the raw material gas into the vacuum chamber. As the film-forming gas, a gas for electric discharge may be used in accordance with needs so as to generate an electric discharge plasma. As the carrier gas and the gas for electric discharge, a known gas may be appropriately used. For example, it is possible to use a noble gas such as helium, argon, neon, or xenon; or hydrogen.

The internal pressure (degree of vacuum) of the vacuum chamber may be appropriately controlled according to the type of the raw material gas and the like. However, the pressure of the space SP is preferably 0.1 Pa to 50 Pa. When the low-pressure plasma CVD method is used for plasma CVD so as to inhibit a gas-phase reaction, the pressure is generally 0.1 Pa to 10 Pa. The electric power of an electrode drum of the plasma-generating device may be appropriately controlled according to the type of the raw material gas, the internal pressure of the vacuum chamber, and the like; however, the electric power is preferably 0.1 kW to 10 kW.

The transport speed (line speed) for transporting the substrate F may be appropriately controlled in accordance with the type of the raw material gas, the internal pressure of the vacuum chamber, and the like. However, the line speed is preferably 0.1 m/minute to 100 m/minute, and more preferably 0.5 m/minute to 20 m/minute. When the line speed satisfies these ranges, wrinkles deriving from the heat in the substrate F are hardly generated.

In the aforementioned production apparatus 10, a film is formed on the substrate F in the following manner.

First, it is preferable to perform a pre-treatment before forming the film so that the amount of outgas generated from the substrate F is reduced to a sufficient degree. The amount of outgas generated from the substrate F may be determined by mounting the substrate F on the production apparatus and measuring the pressure obtained when the internal pressure of the apparatus (internal pressure of the chamber) is reduced. For example, when the internal pressure of the chamber of the production apparatus is 1×10⁻³ Pa or less, it can be determined that the amount of outgas generated from the substrate F has been reduced to a sufficient degree.

Examples of the method for reducing the amount of outgas generated from the substrate F include vacuum drying, heat drying, drying by a combination of these methods, and drying by natural drying. Irrespective of which of these methods is adopted, in order to accelerate drying of the inside of the substrate F wound up in the form of a roll, it is preferable to repeat rewinding (feeding and winding) of the roll during the drying to expose the entire substrate F to a drying environment.

The vacuum drying is performed by putting the substrate F into a pressure-resistant vacuum container and making a vacuum state by evacuating the inside of the vacuum container with use of a depressurizer such as a vacuum pump. The internal pressure of the vacuum container at the time of vacuum drying is preferably 1000 Pa or less, more preferably 100 Pa or less, and still more preferably 10 Pa or less. The evacuation of the inside of the vacuum container may be continuously performed by continuously operating the depressurizer. Alternatively, the evacuation may be intermittently performed by intermittently operating the depressurizer in a state in which the internal pressure is being controlled so as not to be a value equal to or higher than a certain level. The drying time is preferably at least 8 hours or longer, more preferably 1 week or longer, and still more preferably 1 month or longer.

The heat drying is performed by exposing the substrate F to an environment of room temperature or higher. The heating temperature is preferably room temperature or higher and 200° C. or lower, more preferably room temperature or higher and 150° C. or lower. A temperature exceeding 200° C. raises a fear that the substrate F may be deformed. Also, there is a fear that defects may be generated by elution of oligomer components from the substrate F. The drying time may be appropriately selected in accordance with the heating temperature and the heating means to be used.

The heating means may be one that can heat the substrate F to a temperature of room temperature or higher and 200° C. or lower under an ordinary pressure. Among generally known devices, an infrared heating device, a microwave heating device, and a heating drum are preferably used.

Here, the infrared heating device is a device that heats an object by emitting an infrared ray from infrared-ray generating means.

The microwave heating device is a device that heats an object by emitting a microwave from microwave-generating means.

The heating drum is a device that performs heating by heating the drum surface and bringing an object into contact with the drum surface so as to heat the object from the contact part by thermal conduction.

The natural drying is performed by placing the substrate F in an atmosphere of low humidity and maintaining the atmosphere of low humidity by supplying a dry gas (dry air or dry nitrogen) to the atmosphere. For performing the natural drying, it is preferable that the substrate F is placed in the low-humidity environment where the substrate F is placed, together with a desiccant such as silica gel. The drying time is preferably 8 hours or longer, more preferably 1 week or longer, and still more preferably 1 month or longer.

The above drying methods may be performed separately before the substrate F is mounted on the production apparatus, or may be performed inside the production apparatus after the substrate F is mounted on the production apparatus.

Examples of the drying method performed after the substrate F is mounted on the production apparatus include a method of reducing the internal pressure of the chamber in a state in which the substrate F is being fed and transported from the feeding roll. In the method, the roll that the substrate passes through may have a heater, and the roll may be heated so that the roll is used as the aforementioned heating drum for heating.

As another method for reducing the outgas generated from the substrate F, a method of forming an inorganic film in advance on the surface of the substrate F can be mentioned. Examples of the method for forming an inorganic film include physical film-forming methods such as vacuum vapor deposition, (heating deposition), electron beam (EB) vapor deposition, sputtering, and ion plating. The inorganic film may be formed by chemical deposition methods such as thermal CVD, plasma CVD, and atmospheric-pressure CVD. The influence of outgas may be further reduced by performing a drying treatment on the substrate F, which has an inorganic film formed on the surface thereof, by the aforementioned drying methods.

Thereafter, the inside of the vacuum chamber not shown in the drawings is brought into a reduced-pressure environment and, by application of voltage to the first film-forming roll 17 and the second film-forming roll 18, an electric field is formed in the space SP.

In this case, in the magnetic field-forming device 23 and the magnetic field-forming device 24, the aforementioned magnetic field having a form of an endless tunnel is formed. Therefore, when the film-forming gas is introduced, due to electrons released into the magnetic field and the space SP, electric discharge plasma of the film-forming gas having a form of a doughnut is formed along the tunnel. Since the electric discharge plasma can be generated under a low pressure of around several Pa, the internal temperature of the vacuum chamber can be made to be around room temperature.

Meanwhile, the temperature of electrons trapped at a high density in the magnetic field formed by the magnetic field-forming device 23 and the magnetic field-forming device 24 is high. Consequently, when the electrons collide with the film-forming gas, electric discharge plasma is generated. That is, due to the magnetic field and the electric field formed in the space SP, the electrons are confined in the space SP, and therefore, electric discharge plasma of a high density is formed in the space SP. Specifically, in a space overlapped with the magnetic field having a form of an endless tunnel, electric discharge plasma of a high density (high intensity) is formed while, in a space not overlapped with the magnetic field having a form of an endless tunnel, electric discharge plasma of a low density (low intensity) is formed. The intensity of these electric discharge plasmas continuously changes.

When the electric discharge plasma is generated, a large amount of radicals or ions are generated, whereby a plasma reaction proceeds, and a reaction occurs between the raw material gas and the reactant gas contained in the film-forming gas. For example, an organic silicon compound serving as the raw material gas reacts with oxygen serving as the reactant gas and, as a result, an oxidation reaction of the organic silicon compound occurs.

Here, in the space in which the electric discharge plasma of a high intensity is formed, a large amount of energy is given to the oxidation reaction. Therefore, the reaction occurs easily, and mainly a complete oxidation reaction of the organic silicon compound can be allowed to occur. In contrast, in the space in which the electric discharge plasma of a low intensity is formed, a small amount of energy is given to the oxidation reaction. Therefore, the reaction does not proceed easily, and mainly an incomplete oxidation reaction of the organic silicon compound can be allowed to occur.

Here, in the present specification, the “complete oxidation reaction of the organic silicon compound” refers to a process in which a reaction occurs between the organic silicon compound and oxygen, and the organic silicon compound is oxidized and decomposed into silicon dioxide (SiO₂), water, and carbon dioxide.

For example, when the film-forming gas contains hexamethyldisiloxane (HMDSO: (CH₃)₆Si₂O) as a raw material gas and oxygen (O₂) as a reactant gas, as the “complete oxidation reaction”, a reaction described in the following reaction formula (1) occurs, and silicon dioxide is produced.

(CH₃)₆Si₂O+12O₂→6CO₂+9H₂O+2SiO₂ (1)

Also, in the present specification, the “incomplete oxidation reaction of the organic silicon compound” refers to a process in which, instead of the complete oxidation reaction of the organic silicon compound, a reaction that generates not SiO₂ but SiOₓC_{y} (0<x<2, 0<y<2) containing carbons in the structure thereof occurs.

As described above, in the production apparatus 10, the electric discharge plasma having a form of a doughnut is formed on the surface of the first film-forming roll 17 and the second film-forming roll 18. Therefore, the substrate F transported onto the surface of the first film-forming roll 17 and the second film-forming roll 18 alternately passes through the space in which the high-intensity electric discharge plasma is formed and the space in which the low-intensity electric discharge plasma is formed. Consequently, on the surface of the substrate F that passes through the surface of the first film-forming roll 17 and the second film-forming roll 18, the layer (second layer Hb₁ or Hb₂ of FIG. 1) containing a large amount of SiOₓC_{y} generated by the incomplete oxidation reaction is formed in a state of being interposed between layers (first layers Ha₁ or Ha₂ of FIG. 1) containing a large amount of SiO₂ generated by the complete oxidation reaction.

In addition to these, secondary electrons of a high temperature are prevented from flowing into the substrate F due to the action of the magnetic field. Therefore, it is possible to apply a high electric power while keeping the temperature of the substrate F to be low, and a film may be formed at a high speed. A film is mainly deposited only onto the film-forming surface of the substrate F, so that the film-forming rolls are not easily contaminated since the rolls are covered with the substrate F. Therefore, a film may be stably kept being formed for a long period of time.

The laminate film of the present invention has at least a layer: H_{A} and a layer: H_{B}. It is preferable that, first the layer: H_{A} is formed on the substrate side, and thereafter the layer: H_{B} is formed. In forming the layer: H_{B}, it is preferable to form the film at a temperature higher than the temperature of the film surface at the time of forming the layer: H_{A}. As a method for controlling the temperature of the film surface, there can be mentioned methods such as 1. lowering the pressure in the vacuum chamber at the time of forming the film, 2. raising the electric power applied from the power source for plasma generation, 3. reducing the flow rate of the raw material gas (and the flow rate of the oxygen gas), 4. reducing the speed of transporting the substrate F, 5. raising the temperature of the film-forming rolls themselves, and 6. lowering the frequency of the power source for plasma generation at the time of forming the film. The film may be formed by selecting one of these conditions 1 to 6 while fixing the other conditions, and optimizing the selected condition to provide a suitable temperature at the time of forming the film. Alternatively, the film may be formed by changing and optimizing two, three, or more of these conditions to provide a suitable temperature at the time of forming the film.

With regard to the conditions 1 to 4 and 6, optimization is preferably carried out within the above-described ranges. With regard to the condition 5, the temperature on the surface of the first film-forming roll 17 and the second film-forming roll 18 is preferably −10° C. to 80° C.

The laminate film of the present embodiment can be produced through defining the film-forming conditions in this manner and forming the thin film layers on the surface of the substrate by the plasma CVD method using discharge plasma.

### [Organic Electroluminescence Device]

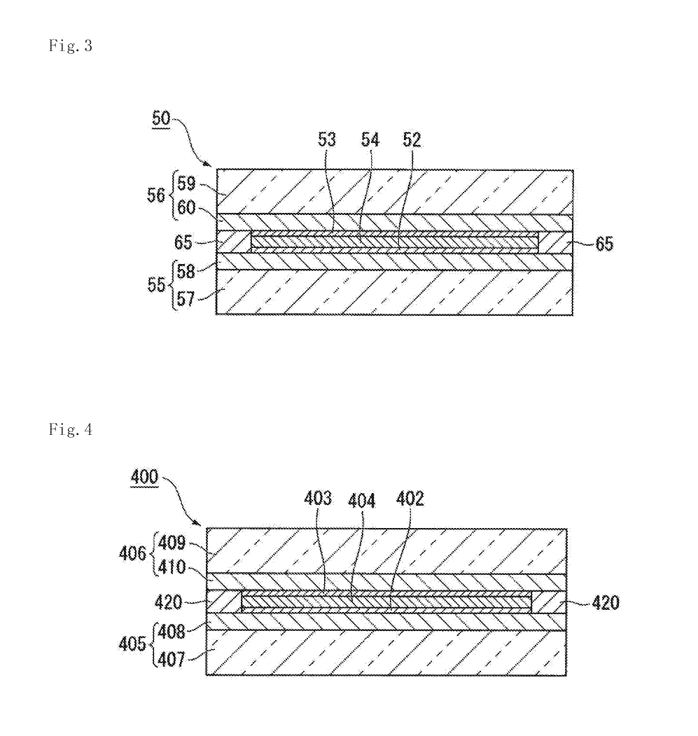

FIG. 3 is a lateral sectional view of an organic electroluminescence device of the present embodiment.

The organic electroluminescence device of the present embodiment is applicable to various electronic devices utilizing light. The organic electroluminescence device of the present embodiment may be a part of a display portion of, for example, a mobile device or the like, a part of an image-forming apparatus such as a printer, a light source (backlight) of, for example, a liquid crystal display panel or the like, or a light source of, for example, an illumination device or the like.

An organic electroluminescence device 50 shown in FIG. 3 has a first electrode 52, a second electrode 53, a luminescent layer 54, a laminate film 55, a laminate film 56, and a sealant 65. As the laminate films 55 and 56, the laminate film of the present embodiment is used. The laminate film 55 has a substrate 57 and a barrier film 58. The laminate film 56 has a substrate 59 and a barrier film 60.

The luminescent layer 54 is disposed between the first electrode 52 and the second electrode 53, and the first electrode 52, the second electrode 53, and the luminescent layer 54 form the organic electroluminescence element. The laminate film 55 is disposed at the side of the first electrode 52 that is opposite to the luminescent layer 54. The laminate film 56 is disposed at the side of the second electrode 53 that is opposite to the luminescent layer 54. Further, the laminate film 55 and the laminate film 56 are bonded to each other by the sealant 65 which is disposed in a state of surrounding the organic electroluminescence element, and form a sealing structure that seals the inside of the organic electroluminescence element.

When an electric power is supplied between the first electrode 52 and the second electrode 53 in the organic electroluminescence device 50, carriers (electrons and holes) are supplied to the luminescent layer 54, and the luminescent layer 54 emits light. The source for supplying electric power to the organic electroluminescence device 50 may be mounted on the organic electroluminescence device 50 or may be disposed outside the device. The light emitted from the luminescent layer 54 is used for displaying or forming images or for illumination in accordance with the purpose of use or the like of an apparatus having the organic electroluminescence device 50.

In the above organic electroluminescence device 50 of the present embodiment, as materials for forming the first electrode 52, the second electrode 53, and the luminescent layer 54 (as materials for forming the organic electroluminescence element), generally known materials are used. Generally, materials for forming an organic electroluminescence element are known to deteriorate easily due to moisture or oxygen. However, in the organic electroluminescence device 50 of the present embodiment, the organic electroluminescence element is sealed by a sealing structure surrounded by the sealant 65 and the laminate films 55 and 56 of the present embodiment that can maintain a high gas barrier property. For this reason, it is possible to obtain a highly reliable organic electroluminescence device 50 whose performance deteriorates little.

Here, in the above description, the organic electroluminescence device 50 of the present embodiment uses the laminate films 55 and 56 of the present embodiment. However, one of the laminate films 55 and 56 may be a gas-barrier substrate having other constitutions.

### [Liquid Crystal Display]

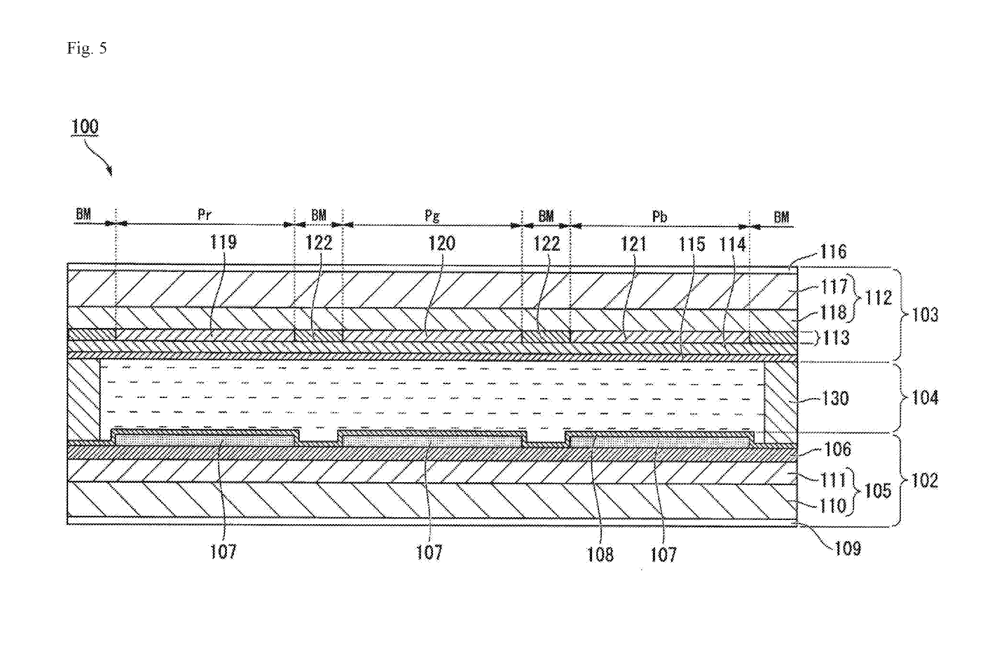

FIG. 5 is a lateral sectional view of a liquid crystal display of the present embodiment.

A liquid crystal display 100 shown in FIG. 5 has a first substrate 102, a second substrate 103, and a liquid crystal layer 104. The first substrate 102 is disposed to face the second substrate 103. The liquid crystal layer 104 is disposed between the first substrate 102 and the second substrate 103. The liquid crystal display 100 is produced by, for example, bonding the first substrate 102 to the second substrate 103 by using a sealant 130, and enclosing the liquid crystal layer 104 in a space surrounded by the first substrate 102, the second substrate 103, and the sealant 130.

The liquid crystal display 100 has a plurality of pixels. The plurality of pixels are arranged in the form of a matrix. The liquid crystal display 100 of the present embodiment can display a full color image. Each of the pixels of the liquid crystal display 100 has a subpixel Pr, a subpixel Pg, and a subpixel Pb. Between the subpixels, a light-shielding region BM is formed. The three types of subpixels emit color lights, which differ from each other in terms of grayscale, to the display side of an image in response to image signals. In the present embodiment, red light is emitted from the subpixel Pr; green light is emitted from the subpixel Pg; and blue light is emitted from the subpixel Pb. A combination of the lights of three colors that are emitted from the three types of subpixels is visually recognized, and as a result, one pixel of full color is displayed.

The first substrate 102 has a laminate film 105, an element layer 106, a plurality of pixel electrodes 107, an alignment film 108, and a polarizer plate 109. The pixel electrode 107 and a common electrode 114, which will be described later, form a pair of electrodes. The laminate film 105 has a substrate 110 and a barrier film 111. The substrate 110 is in the form of a thin plate or a film. The barrier film 111 is formed on one surface of the substrate 110. The element layer 106 is formed by being laminated on the barrier film 111 formed on the substrate 110. Each of the plurality of pixel electrodes 107 is disposed on the element layer 106 independently for the subpixel of the liquid crystal display 100. The alignment film 108 is disposed on the pixel electrodes 107 and between the pixel electrodes 107 over the plurality of subpixels.

The second substrate 103 has a laminate film 112, a color filter 113, a common electrode 114, an alignment film 115, and a polarizer plate 116. The laminate film 112 has a substrate 117 and a barrier film 118. The substrate 117 is in the form of a thin plate or a film. The barrier film 118 is formed on one surface of the substrate 117. The color filter 113 is formed by being laminated on the barrier film 111 formed on the substrate 110. The common electrode 114 is disposed on the color filter 113. The alignment film 115 is disposed on the common electrode 114.

The first substrate 102 and the second substrate 103 are disposed so that the pixel electrode 107 faces the common electrode 114, and bonded to each other in a state in which the liquid crystal layer 104 is interposed therebetween. The pixel electrodes 107, the common electrode 114, and the liquid crystal layer 104 form a liquid crystal display element. Furthermore, the laminate film 105 and the laminate film 112 form a sealing structure that seals the inside of the liquid crystal display element, in cooperation with the sealant 130 that is disposed to surround the liquid crystal display element.

In the liquid crystal display 100, the laminate film 105 and the laminate film 112 of the present embodiment having a high gas barrier property form a part of the sealing structure that seals the inside of the liquid crystal display element. Therefore, it is possible to obtain a highly reliable liquid crystal display 100 which is less likely to experience deterioration of the liquid crystal display element due to oxygen or moisture in the air and less likely to show performance degradation.

Regarding the liquid crystal display 100 of the present embodiment, the case of using the laminate films 105 and 112 of the present embodiment has been described. However, one of the laminate films 105 and 112 may be a gas-barrier substrate having other constitutions.

### [Photoelectric Conversion Device]

FIG. 4 is a lateral sectional view of a photoelectric conversion device of the present embodiment. The photoelectric conversion device of the present embodiment is usable for various devices that convert light energy to electric energy, such as light-detecting sensors or solar cells.

A photoelectric conversion device 400 shown in FIG. 4 has a first electrode 402, a second electrode 403, a photoelectric conversion layer 404, a laminate film 405, and a laminate film 406. The laminate film 405 has a substrate 407 and a barrier film 408. The laminate film 406 has a substrate 409 and a barrier film 410. The photoelectric conversion layer 404 is disposed between the first electrode 402 and the second electrode 403, and the first electrode 402, the second electrode 403, and the photoelectric conversion layer 404 form a photoelectric conversion element.

The laminate film 405 is disposed at the side of the first electrode 402 that is opposite to the photoelectric conversion layer 404. The laminate film 406 is disposed at the side of the second electrode 403 that is opposite to the photoelectric conversion layer 404. The laminate film 405 and the laminate film 406 are bonded to each other by a sealant 420 that is disposed to surround the photoelectric conversion element, and form a sealing structure that seals the inside of the photoelectric conversion element.

In the photoelectric conversion device 400, the first electrode 402 is a transparent electrode, and the second electrode 403 is a reflector electrode. In the photoelectric conversion device 400 of the present example, light energy of light having entered the photoelectric conversion layer 404 through the first electrode 402 is converted into electric energy in the photoelectric conversion layer 404. This electric energy is taken out of the photoelectric conversion device 400 via the first electrode 402 and the second electrode 403. The materials and the like of the respective constituent elements, which are disposed in an optical path of the light entering the photoelectric conversion layer 404 from the outside of the photoelectric conversion device 400, are appropriately selected so that at least the part corresponding to the optical path has light permeability. The constituent elements disposed in a part not included in the optical path of the light coming from the photoelectric conversion layer 404 may be formed of materials having light permeability or materials that partially or totally block the light.

In the photoelectric conversion device 400 of the present embodiment, generally known materials are used as the first electrode 402, the second electrode 403, and the photoelectric conversion layer 404. In the photoelectric conversion device 400 of the present embodiment, the photoelectric conversion element is sealed with a sealing structure surrounded by the laminate films 405 and 406 of the present embodiment having a high gas barrier property and the sealant 420. Therefore, it is possible to obtain a highly reliable photoelectric conversion device 400 which is less likely to undergo deterioration of the photoelectric conversion layer or electrodes due to oxygen or moisture in the air and less likely to show performance degradation.

Here, regarding the photoelectric conversion device 400 of the present embodiment, the case in which the photoelectric conversion element is interposed between the laminate films 405 and 406 of the present embodiment has been described. However, one of the laminate films 405 and 406 may be a gas-barrier substrate having other constitutions.

Up to now, examples of the preferable embodiments according to the present invention have been described with reference to the drawings. However, needless to say, the present invention is not limited to these examples. The form, combination, and the like of the respective constituent members described in the above examples are merely examples, and within a range that does not depart from the gist of the present invention, these may be modified in various ways based on requirements of design and the like.

### EXAMPLES

Hereafter, the present invention will be more specifically described based on Examples and Comparative Examples. However, the present invention is not limited to the Examples given below. Each of the values measured for the laminate film was obtained by measuring the film by the following method.

### [Measuring Method]

### (1) Measurement of Thickness of Thin Film Layer

A thickness of the thin film layer was determined by observing a cross-section of a slice of the thin film layer prepared by a Focused Ion Beam (FIB) process, by using a transmission electron microscope (HF-2000 manufactured by Hitachi High-Technologies Corporation).

### (FIB Conditions)

Apparatus: SMI-3050 (manufactured by SII NanoTechnology Inc.)

Acceleration voltage: 30 kV

### (2) Measurement of Water Vapor Permeability

The water vapor permeability of the laminate film was measured by the calcium corrosion method (method described in JP-A-2005-283561) under conditions with a temperature of 40° C. and a humidity of 90% RH.

### (3) Distribution Curve of Each Element in Thin Film Layer

Regarding the thin film layer of the laminate film, distribution curves of silicon atoms, oxygen atoms and carbon atoms were obtained by XPS depth profile measurement performed under the following conditions. Each of the curves was made into a graph in which the abscissa represents a distance (nm) from the surface of the thin film layer, and the ordinate represents a percentage of the atoms of each element.

### (Measurement Conditions)

Etching ion species: argon (Ar⁺)

Etching rate (value as converted in terms of SiO₂ thermal oxide film): 0.05 nm/sec

Etching interval (value as converted in terms of SiO₂ thermal oxide film): 10 nm

X-ray photoelectron spectroscopy instrument: VG Theta Probe manufactured by Thermo Fisher Scientific K.K.

Irradiation X-ray: single-crystal spectroscopic AlKα

Spot shape and spot diameter of X-ray: ellipse of 800×400 μm

### (4) Measurement of Light Transmittance

A light transmittance spectrum of the laminate film was measured using a UV-visible near infrared spectrophotometer (manufactured by JASCO Corporation, trade name of Jasco V-670) based on JIS R1635, and a visible light transmittance at a wavelength of 550 nm was taken as a light transmittance of the laminate film.

### (Measuring Conditions)

Integrating sphere: None

Range of wavelength measured: 190 to 2700 nm

Spectrum width: 1 nm

Wavelength scanning speed: 2000 nm/minute

Response: Fast

### (5) Measurement of Density Distribution of Thin Film Layer

The measurement of the density distribution of the thin film layer was conducted by Rutherford Backscattering Spectrometry (RBS) and Hydrogen Forward scattering Spectrometry (HFS). The measurement by the RBS method and the HFS method were carried out by using the following common measuring instrument.

### (Measuring Instruments)

Accelerator: accelerator from National Electrostatics Corp (NEC)

Measuring instrument: end station manufactured by Evans Co., Ltd.

(i. Measurement by RBS Method)

Onto the thin film layer of the laminate film, He ion beams were let to be incident in a normal line direction of the surface of the thin film layer, and energy of He ions scattering backward relative to the incidence direction was detected, so as to obtain an RBS spectrum. In RBS, two detectors were used to measure the spectrum data of 160° and about 1150 simultaneously.

### Analysis Conditions

He⁺⁺ ion beam energy: 2.275 MeV

RBS detection angle: 160°

Grazing Angle relative to the ion beam incidence direction: about 115°

Analysis mode: RR (Rotation Random)

(ii. Measurement by HFS Method)

Onto the thin film layer of the laminate film, He ion beams were allowed to be incident in a direction forming an angle of 75° relative to the normal line direction of the surface of the thin film layer (a direction forming an angle of elevation of 15° relative to the surface of the thin film layer), and energy and yield of hydrogen scattering forward at an angle of 30° relative to the ion beam incidence direction were detected, so as to obtain an HFS spectrum.

Analysis Conditions

He⁺⁺ ion beam energy: 2.275 MeV

Grazing Angle relative to the ion beam incidence direction: about 30°

(iii. Modelizing Conditions)

The thin film layer H was supposed to be a laminate model made of a plurality of layers. The density within each layer and the compositional ratio of silicon atoms, oxygen atoms, carbon atoms, and hydrogen atoms constituting each layer were assumed to be constant. Next, the thickness, the density, and the compositional ratio of elements in each layer were respectively set to meet the following conditions. The laminate model was set so that the thickness of each layer would be 10% or more of the thickness of the whole layer, and the integrated values of the spectra of the laminate film that were obtained by Rutherford backscattering (160°) and hydrogen forward scattering (30°) and the calculated values of the spectra that were calculated from the laminate model would fall respectively within an error of 5%.

The density distribution of the thin film layer within the measurement range was determined from the number of silicon atoms, the number of carbon atoms, and the number of oxygen atoms determined by the RBS method and the number of hydrogen atoms determined by the HFS method. Correction of the density distribution was made by the following formula based on the true thickness determined in “(1) Measurement of thickness of thin film layer”.

Dreal=(DRBS×TRBS)/Treal

Dreal: true density, DRBS: density determined by the RBS method and the HFS method, TRBS: thickness determined by the RBS method and the HFS method, Treal: true thickness

### Example 1

A laminate film 1 was produced using a film-forming apparatus such as shown in FIG. 2.

That is, a biaxially oriented polyethylene naphthalate film (PEN film, thickness: 100 μm, width: 350 mm, manufactured by Teijin DuPont Films Japan Limited, trade name of “Teonex Q65FA”) was used as the substrate (substrate F), and this was mounted on the feeding roll 11.

Thereafter, to a place where a magnetic field in the form of an endless tunnel had been formed in a space between the first film-forming roll 17 and the second film-forming roll 18, a film-forming gas (mixed gas consisting of raw material gas (HMDSO) and reactant gas (oxygen gas)) was supplied; electric power was supplied to each of the first film-forming roll 17 and the second film-forming roll 18 so as to generate electric discharge between the first film-forming roll 17 and the second film-forming roll 18; the film was transported from the first film-forming roll 17 to the second film-forming roll 18; and a thin film was formed by the plasma CVD method under the film-forming condition 1. Next, the film was transported from the second film-forming roll 18 to the first film-forming roll 17, and a thin film was formed by the plasma CVD method under the film-forming condition 2. Through this step, the laminate film 1 was obtained.

### (Film-Forming Condition 1)

Amount of raw material gas supplied: 50 sccm (0° C., 1 atm standard)

Amount of oxygen gas supplied: 500 sccm (0° C., 1 atm standard)

Degree of vacuum of inside of vacuum chamber: 3 Pa

Power applied from power source for plasma generation: 0.8 kW

Frequency of power source for plasma generation: 70 kHz

Transport speed of film: 0.5 m/minute

### (Film-Forming Condition 2)

Amount of raw material gas supplied: 25 sccm (0° C., 1 atm standard)

Amount of oxygen gas supplied: 250 sccm (0° C., 1 atm standard)

Degree of vacuum of inside of vacuum chamber: 1 Pa

Power applied from power source for plasma generation: 0.8 kW

Frequency of power source for plasma generation: 70 kHz

Transport speed of film: 0.5 m/minute

The thickness of the thin film layer of the fabricated laminate film 1, as determined by TEM observation of a cross-section processed by FIB, was 474 nm.

The distribution of the density of the thin film layer of the fabricated laminate film 1 was measured by Rutherford backscattering/hydrogen forward scattering spectrometry (RBS/HFS). Also, a laminate model was supposed, and the validity of the model was verified.

### 1. Rutherford Backscattering (160°) Measurement

The integrated value of 500 to 88 channels of the RBS spectrum obtained by Rutherford backscattering (160°) (corresponding to the area of the RBS spectrum and being a sum of Si, O, and C in the thin film layer) was 106581.

### 2. Rutherford Backscattering (113°) Measurement

The integrated value of 500 to 128 channels of the RBS spectrum obtained by Rutherford backscattering (113°) (corresponding to the area of the RBS spectrum and being a sum of Si, O, and C in the thin film layer) was 278901.

### 3. Hydrogen Forward Scattering (30°) Measurement

The integrated value of 500 to 75 channels of the HFS spectrum obtained by hydrogen forward scattering (30°) (corresponding to the area of the HFS spectrum) was 16832.5.

### 4. Laminate Model

From the results of the spectrum of Rutherford backscattering (160°) measurement, Rutherford backscattering (113°) measurement, and hydrogen forward scattering (30°) measurement, a laminate model made of five layers was supposed as follows. When the layers of the laminate model made of the five layers were named as the first layer, second layer, third layer, fourth layer, and fifth layer from the substrate side, it was supposed that the density of the first layer was 2.095 g/cm³, and the compositional ratio of the elements of the first layer included silicon atoms at 18.3 at %, oxygen atoms at 39.5 at %, carbon atoms at 22.0 at %, and hydrogen atoms at 20.2 at %; the density of the second layer was 2.121 g/cm³, and the compositional ratio of the elements of the second layer included silicon atoms at 20.3 at %, oxygen atoms at 41.7 at %, carbon atoms at 19.5 at %, and hydrogen atoms at 18.5 at %; the density of the third layer was 2.097 g/cm³, and the compositional ratio of the elements of the third layer included silicon atoms at 18.6 at %, oxygen atoms at 38.6 at %, carbon atoms at 22.3 at %, and hydrogen atoms at 20.5 at %; the density of the fourth layer was 2.153 g/cm³, and the compositional ratio of the elements of the fourth layer included silicon atoms at 22.3 at %, oxygen atoms at 52.5 at %, carbon atoms at 14.0 at %, and hydrogen atoms at 11.2 at %; the density of the fifth layer was 2.183 g/cm³, and the compositional ratio of the elements of the fifth layer included silicon atoms at 23.2 at %, oxygen atoms at 56.8 at %, carbon atoms at 15.0 at %, and hydrogen atoms at 5.0 at %.

### 5. Verification of Laminate Model

The integrated value of 500 to 88 channels of the spectrum obtained by Rutherford backscattering (160°) measurement (corresponding to the area of the RBS spectrum and being a sum of Si, O, and C in the thin film layer), as calculated from the laminate model, was 103814.8, which was 97.4% of the actually measured spectrum, exhibiting an area within ±5%, so that the RBS spectrum was sufficiently reproduced. The integrated value of 500 to 128 channels of the spectrum of Rutherford backscattering (113°) measurement (corresponding to the area of the RBS spectrum and being a sum of Si, O, and C in the thin film layer), as calculated from the laminate model, was 275116.3, which was 98.6% of the actually measured spectrum, exhibiting an area within ±5%, so that the RBS spectrum was sufficiently reproduced. The integrated value of 500 to 75 channels of the spectrum of hydrogen forward scattering (30°) measurement (corresponding to the area of the HFS spectrum), as calculated from the laminate model, was 17502.6, which was 104% of the actually measured spectrum, exhibiting an area within +5%, so that the HFS spectrum was sufficiently reproduced. From the above, it was determined that the above laminate model was valid.

### 6. Results

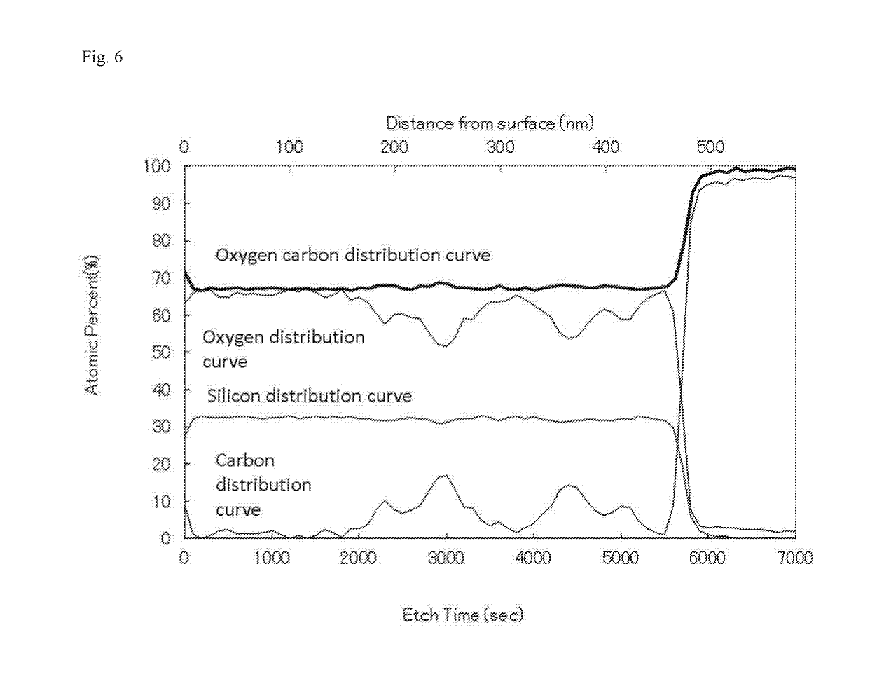

The density X of the layer A (first layer) of this laminate film 1, as determined from the above model, was 2.095 g/cm³, and the density Y of the layer B (fifth layer) was 2.183 g/cm³. These satisfied the relationship of (1), and the value of Y/X was 1.042. The silicon distribution curve, the oxygen distribution curve, and the carbon distribution curve of the thin film layer of the laminate film 1 (XPS depth profile measurement) are shown in FIG. 6. The silicon distribution curve, the oxygen distribution curve, and the carbon distribution curve were each continuous, and the carbon distribution curve had at least one extremal value. Also, it is understood that the thin film layer has silicon atoms, oxygen atoms and carbon atoms, and also has hydrogen atoms from the hydrogen forward scattering (30°) measurement.

The water vapor permeability of the laminate film 1 was 9.3×10⁻⁵ g/m²/day, confirming that the laminate film 1 had an excellent gas barrier property. Also, the light transmittance was 88%, showing that the laminate film 1 had a high transparency as well.

### Comparative Example 1

A laminate film 2 was formed under the following conditions.

That is, a biaxially oriented polyethylene naphthalate film (PEN film, thickness: 100 μm, width: 350 mm, manufactured by Teijin DuPont Films Japan Limited, trade name of “Teonex Q65FA”) was used as the substrate (substrate F), and this was mounted on the feeding roll 11.

Thereafter, to a place where a magnetic field in the form of an endless tunnel had been formed in a space between the first film-forming roll 17 and the second film-forming roll 18, a film-forming gas (mixed gas consisting of raw material gas (HMDSO) and reactant gas (oxygen gas)) was supplied; electric power was supplied to each of the first film-forming roll 17 and the second film-forming roll 18 so as to generate electric discharge between the first film-forming roll 17 and the second film-forming roll 18; the film was transported from the first film-forming roll 17 to the second film-forming roll 18; and a thin film was formed by the plasma CVD method under the film-forming condition 3. Next, the film was transported from the second film-forming roll 18 to the first film-forming roll 17, and a thin film was formed by the plasma CVD method under the film-forming condition 4. Through this step, the laminate film 2 was obtained.

### (Film-Forming Condition 3)

Amount of raw material gas supplied: 25 sccm (0° C., 1 atm standard)

Amount of oxygen gas supplied: 250 sccm (0° C., 1 atm standard)

Degree of vacuum of inside of vacuum chamber: 1 Pa

Power applied from power source for plasma generation: 0.8 kW

Frequency of power source for plasma generation: 70 kHz

Transport speed of film: 0.5 m/minute

### (Film-Forming Condition 4)

Amount of raw material gas supplied: 50 sccm (0° C., 1 atm standard)

Amount of oxygen gas supplied: 500 sccm (00° C., 1 atm standard)

Degree of vacuum of inside of vacuum chamber: 3 Pa

Power applied from power source for plasma generation: 0.8 kW

Frequency of power source for plasma generation: 70 kHz

Transport speed of film: 0.5 m/minute

The thickness of the thin film layer of the fabricated laminate film 2, as determined by TEM observation of a cross-section processed by FIB, was 446 nm.

The distribution of the density of the thin film layer of the fabricated laminate film 2 was measured by Rutherford backscattering/hydrogen forward scattering spectrometry (RBS/HFS). Also, a laminate model was supposed, and the validity of the model was verified.

### 1. Rutherford Backscattering (160°) Measurement

The integrated value of 500 to 88 channels of the RBS spectrum obtained by Rutherford backscattering (160°) (corresponding to the area of the RBS spectrum and being a sum of Si, O, and C in the thin film layer) was 98462.

### 2. Rutherford Backscattering (114°) Measurement

The integrated value of 500 to 140 channels of the RBS spectrum obtained by Rutherford backscattering (114°) (corresponding to the area of the RBS spectrum and being a sum of Si, O, and C in the thin film layer) was 248650.

### 3. Hydrogen Forward Scattering (30°) Measurement

The integrated value of 500 to 75 channels of the HFS spectrum obtained by hydrogen forward scattering (30°) (corresponding to the area of the HFS spectrum) was 20896.7. The integrated value of 500 to 75 channels of the spectrum (corresponding to the area of the HFS spectrum), as calculated from the laminate model, was 20873.9, which was 99.9% of the actually measured spectrum, exhibiting an area within ±5%, so that the HFS spectrum was sufficiently reproduced.

### 4. Laminate Model

From the results of the spectrum of Rutherford backscattering (160°) measurement, Rutherford backscattering (114°) measurement, and hydrogen forward scattering (30°) measurement, a laminate model made of three layers was supposed as follows. When the layers of the laminate model made of the three layers were named as the first layer, second layer, and third layer from the substrate side, it was supposed that the density of the first layer was 2.124 g/cm³, and the compositional ratio of the elements of the first layer included silicon atoms at 23.0 at %, oxygen atoms at 51.5 at %, carbon atoms at 10.5 at %, and hydrogen atoms at 15.0 at %; the density of the second layer was 2.104 g/cm³, and the compositional ratio of the elements of the second layer included silicon atoms at 21.3 at %, oxygen atoms at 43.7 at %, carbon atoms at 15.0 at %, and hydrogen atoms at 20.0 at %; the density of the third layer was 2.117 g/cm³, and the compositional ratio of the elements of the third layer included silicon atoms at 21.4 at %, oxygen atoms at 45.6 at %, carbon atoms at 15.0 at %, and hydrogen atoms at 18.0 at %.

### 5. Verification of Laminate Model

The integrated value of 500 to 88 channels of the spectrum obtained by Rutherford backscattering (160°) measurement (corresponding to the area of the RBS spectrum and being a sum of Si, O, and C in the thin film layer), as calculated from the laminate model, was 98037.8, which was 99.6% of the actually measured spectrum, exhibiting an area within ±5%, so that the RBS spectrum was sufficiently reproduced. The integrated value of 500 to 140 channels of Rutherford backscattering (114°) measurement (corresponding to the area of the RBS spectrum and being a sum of Si, O, and C in the thin film layer), as calculated from the laminate model, was 238656.8, which was 96.0% of the actually measured spectrum, exhibiting an area within ±5%, so that the RBS spectrum was sufficiently reproduced. The integrated value of 500 to 75 channels of the spectrum of hydrogen forward scattering (30°) measurement (corresponding to the area of the HFS spectrum), as calculated from the laminate model, was 20873.9, which was 99.9% of the actually measured spectrum, exhibiting an area within ±5%, so that the HFS spectrum was sufficiently reproduced. From the above, it was determined that the above laminate model was valid.

### 6. Results

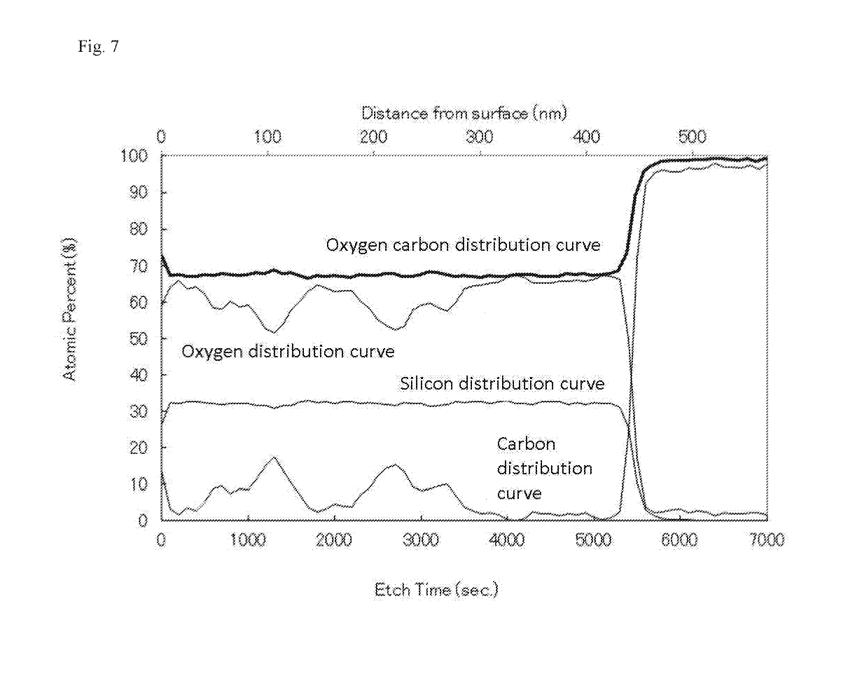

The density X of the layer A of this laminate film 2, as determined from the above model, was 2.124 g/cm³ (first layer), and the density Y of the layer B (third layer) was 2.117 g/cm³. These did not satisfy the relationship of (1), and the value of Y/X was 0.997. The silicon distribution curve, the oxygen distribution curve, and the carbon distribution curve of the thin film layer of the laminate film 1 (XPS depth profile measurement) are shown in FIG. 7. The silicon distribution curve, the oxygen distribution curve, and the carbon distribution curve were each continuous, and the carbon distribution curve had at least one extremal value. Also, it is understood that the thin film layer has silicon atoms, oxygen atoms and carbon atoms, and also has hydrogen atoms from the hydrogen forward scattering (30°) measurement.

The water vapor permeability of the laminate film 2 was 4.1×10⁻⁴ g/m²/day. Also, the light transmittance was 87%.

From these results, it has been confirmed that the laminate film of the present invention has a high gas barrier property. The laminate film of the present invention can be suitably used in an organic electroluminescence device, a photoelectric conversion device, or a liquid crystal display.

### INDUSTRIAL APPLICABILITY

The laminate film of the present invention has a high gas barrier property and is useful for an organic electroluminescence device, a photoelectric conversion device, a liquid crystal display, or the like.

### DESCRIPTION OF REFERENCE SIGNS

10 production apparatus
11 feeding roll
12 winding roll
13 to 16 transport roll
17 first film-forming roll
18 second film-forming roll
19 gas supplying pipe
20 power source for plasma generation
23, 24 magnetic field-forming device
50 organic electroluminescence device
100 liquid crystal display
400 photoelectric conversion device
55, 56, 105, 112, 405, 406 laminate film
F film (substrate)
SP space (film-forming space)

1. A laminate film having a substrate and at least one thin film layer which has been formed on at least one surface of the substrate, wherein at least one thin film layer satisfies all of conditions (i) to (iii) below:
(i) the thin film layer contains silicon atoms, oxygen atoms, carbon atoms, and hydrogen atoms,
(ii) in a silicon distribution curve, an oxygen distribution curve, and a carbon distribution curve respectively showing a relationship between a distance from a surface of the thin film layer in a thickness direction of the thin film layer and a ratio of an amount of silicon atoms (atomic ratio of silicon), a ratio of an amount of oxygen atoms (atomic ratio of oxygen), and a ratio of an amount of carbon atoms (atomic ratio of carbon), relative to a sum amount of the silicon atoms, the oxygen atoms and the carbon atoms which are contained in the thin film layer at a position located at the aforesaid distance,
each the silicon distribution curve, the oxygen distribution curve, and the carbon distribution curve are continuous, and the carbon distribution curve has at least one extremal value, and
(iii) when the thin film layer is supposed as a laminate made of plurality of layers that is modeled under conditions below, a density X (g/cm³) of a layer A that is closest to a substrate side and a density Y (g/cm³) of a layer B having a highest density other than the layer A satisfy a condition represented by formula (1) below:
X<Y (1),
where the modelizing conditions are such that:
one thin film layer is supposed to be a laminate model made of a plurality of layers; a density within each layer and a compositional ratio of atoms constituting each layer are assumed to be constant; a thickness, a density, and a compositional ratio of elements in each layer are respectively set to meet conditions below; the laminate model is set so that a thickness of each layer is 10% or more of a thickness of a whole layer, and integrated values of spectra of the laminate film that are obtained by Rutherford backscattering (160°) and hydrogen forward scattering (30°) and calculated values of spectra that are calculated from the laminate model respectively fall within an error of 5%.

2. The laminate film according to claim 1, wherein the density Y is 1.34 g/cm³ to 2.65 g/cm³.

3. The laminate film according to claim 1, wherein the density Y is 1.80 g/cm³ to 2.65 g/cm³.

4. The laminate film according to claim 1, wherein the density X is 1.33 g/cm³ to 2.62 g/cm³.

5. An organic electroluminescence device having the laminate film according to claim 1.

6. A photoelectric conversion device having the laminate film according to claim 1.

7. A liquid crystal display having the laminate film according to claim 1.
